(19) United States
(12) Patent Application Publication
(10) Pub. No.: US 2025/0022746 A1
(43) Pub. Date: Jan. 16, 2025

(54) ISOLATION BETWEEN DEVICE AREAS

(71) Applicant: Taiwan Semiconductor Manufacturing Company, Ltd., Hsinchu (TW)

(72) Inventors: Tzu-Ging Lin, Kaohsiung (TW); Chih-Chang Hung, Hsinchu (TW); Shun-Hui Yang, Taoyuan (TW); Tzu-Chung Wang, Hsinchu (TW); Yun-Chen WU, Hsinchu (TW)

(73) Assignee: Taiwan Semiconductor Manufacturing Company, Ltd., Hsinchu (TW)

(21) Appl. No.: 18/352,583

(22) Filed: Jul. 14, 2023

(51) Int. Cl. H01L 21/762; H01L 21/768; H01L 21/8238; H01L 27/092; H01L 29/06; H01L 29/423; H01L 29/66; H01L 29/775; H01L 29/78; H01L 29/786

(52) U.S. Cl. CPC H01L 21/76224; H01L 21/76843; H01L 21/823821; H01L 21/823878; H01L 27/0924; H01L 29/0673; H01L 29/42392; H01L 29/66439; H01L 29/66545; H01L 29/66795; H01L 29/775; H01L 29/7851; H01L 29/78696

(57) ABSTRACT

Provided are semiconductor devices and methods for fabricating such devices. An exemplary method includes forming a fin structure over a semiconductor material; forming a sacrificial layer over the semiconductor material; removing a portion of the fin structure and an overlying portion of the sacrificial layer located over the portion of the fin structure to form a trench; forming an insulation structure in the trench, wherein an adjacent portion of the sacrificial layer is adjacent an end wall of the insulation structure; removing the adjacent portion to form a cavity partially defined by the end wall; lining the cavity with a liner, wherein an end portion of the liner is located on the end wall of the insulation structure; filling the cavity with a fill material; removing the end portion of the liner to form an opening; and forming an end isolation structure in the opening.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, to reduce OFF-state current, and to reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFETs and GAA devices are compatible with conventional complementary metal-oxide-semiconductor (CMOS) processes and their three-dimensional structure allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIG. 2 is a flow chart illustrating a method, in accordance with some embodiments.

FIGS. 3-7 and 9-10 are cross-sectional views of a multi-gate device at various stages of fabrication, in accordance with some embodiments.

FIG. 8 is an overhead schematic of elements of the fabrication stage of FIG. 7, in accordance with some embodiments.

FIG. 11 is an overhead schematic of elements of the fabrication stage of FIG. 10, in accordance with some embodiments.

FIGS. 12 and 13 are TEM views along a Y-cut cross-sectional view of the multi-gate device of FIG. 10, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow.

Embodiments of the present disclosure offer advantages over the existing art, though it is understood that other embodiments may offer different advantages, not all advantages are necessarily discussed herein, and no particular advantage is required for all embodiments.

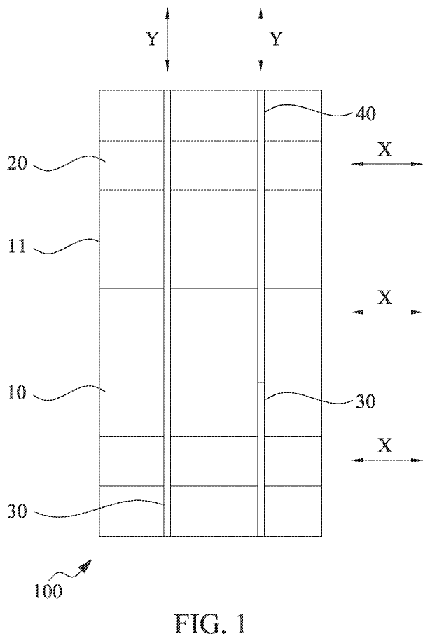

For purposes of the discussion that follows, FIG. 1 provides a simplified top-down layout view of a semiconductor device 100, such as a multi-gate device 100. Multi-gate devices 100 include those transistors whose gate structures are formed on at least two-sides of a channel region. These multi-gate devices may include a P-type metal-oxide-semiconductor device or an N-type metal-oxide-semiconductor multi-gate device.

In various embodiments, the multi-gate device 100 may include a FinFET device, gate-all-around (GAA) device, or other type of multi-gate device. A GAA device includes any device that has its gate structure, or portion thereof, formed on four-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, “nanosheet channel” is intended to include nanowire channel and bar-shaped channel configurations. Presented herein are embodiments of devices 100 that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The multi-gate device 100 is formed over a substrate 10. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

FIG. 1 is an overhead view of a unit cell 11, i.e., a portion of the semiconductor substrate 10. As shown, parallel active regions 20 are spaced apart from one another and extend in an X-direction. Further, parallel gate lines 30 are spaced apart from one another and extend in a Y-direction perpendicular to the X-direction. Exemplary gate lines 30 are formed from conductive material such as metal and form gate structures for the multi-gate device 100.

As further shown in FIG. 1, a cut region or trench is formed in one gate line 30 and is filled with insulation to form an insulation structure 40 that may isolate adjacent devices from one another as described below. As used herein, “insulation”, “isolation”, and “dielectric” may be considered to be synonyms and are used in different instances only for purposes of clarity of description.

Methods described herein relate to the formation of the insulation structure 40, such as a Continuous Poly On Diffusion Edge (CPODE) structure 40, that divides a fin in two. In certain embodiments, a portion of a selected fin structure is removed and replaced with insulation material.

For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an isolation region between neighboring active regions, and thus neighboring transistors, by performing a dry etching process along an active edge (e.g., at a boundary of adjacent active regions) to form a cut region and filling the cut region with a dielectric, such as silicon nitride (SiN).

Before the CPODE process, the active edge may include a GAA dummy structure having a gate stack and a plurality of channels (e.g., nanosheet channels). The plurality of channels may each include a chemical oxide layer formed thereon, and high-K dielectric/metal gate layers may be formed over the chemical oxide layer and between adjacent channels of the plurality of channels. In addition, inner spacers may be disposed between adjacent channels at lateral ends of the plurality of channels. In various examples, source/drain epitaxial (epi) layers of adjacent active regions are disposed on either side of the GAA dummy structure (formed at the active edge), such that the adjacent source/drain epi layers are in contact with the inner spacers and plurality of channels of the GAA dummy structure.

In embodiments herein, a CPODE-first processing method, i.e., before metal gate formation, is utilized. Further, the cut-metal process for patterning metal gate lines into separate metal gate structures is used to also cut the line ends of the CPODE insulation structure. Specifically, the replacement metal gate formation process includes forming a high-K gate dielectric as the outer layer of the metal gate structure in a trench that is partially defined by the already-formed CPODE insulation structure. Thus, a layer of the high-K gate dielectric is formed on the end wall of the CPODE insulation structure. Such a layer can cause parasitic capacitance when located near a source/drain region. As used herein, “source/drain region(s)” may refer to a source region or a drain region, individually or collectively depending on the context. Further, such a layer can cause a shift of the threshold voltage. The process described herein removes the layer of the high-K gate dielectric located on the end wall of the CPODE insulation structure.

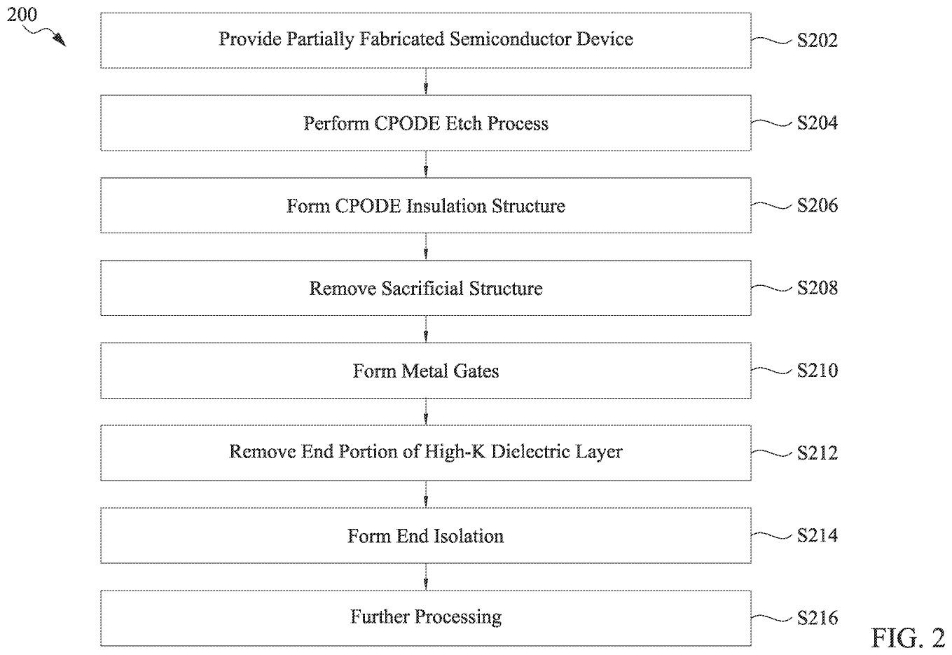

Referring to FIG. 2, illustrated therein is a method 200 of fabrication of a semiconductor device 100 (such as a multi-gate device) using a CPODE process, in accordance with various embodiments. Method 200 is discussed below with reference to a GAA device having a channel region that may be referred to as a nanosheet and which may include various geometries (e.g., cylindrical, bar-shaped) and dimensions. However, it will be understood that aspects of method 200, including the disclosed CPODE process, may be equally applied to other types of multi-gate devices without departing from the scope of the present disclosure. In some embodiments, method 200 may be used to fabricate the multi-gate device 100, described above with reference to FIG. 1. Thus, one or more aspects discussed above with reference to the multi-gate device 100 may also apply to method 200. It is understood that method 200 includes steps having features of a complementary metal-oxide-semiconductor (CMOS) technology process flow and thus, are only described briefly herein. Also, additional steps may be performed before, after, and/or during method 200.

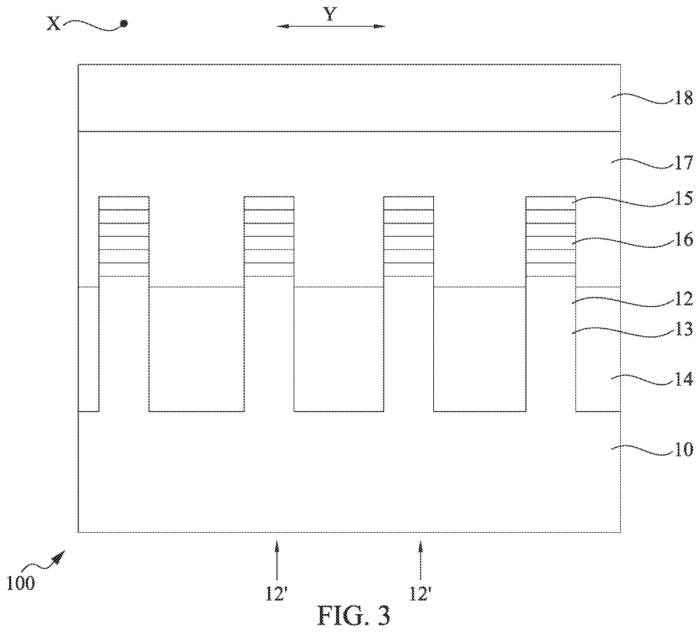

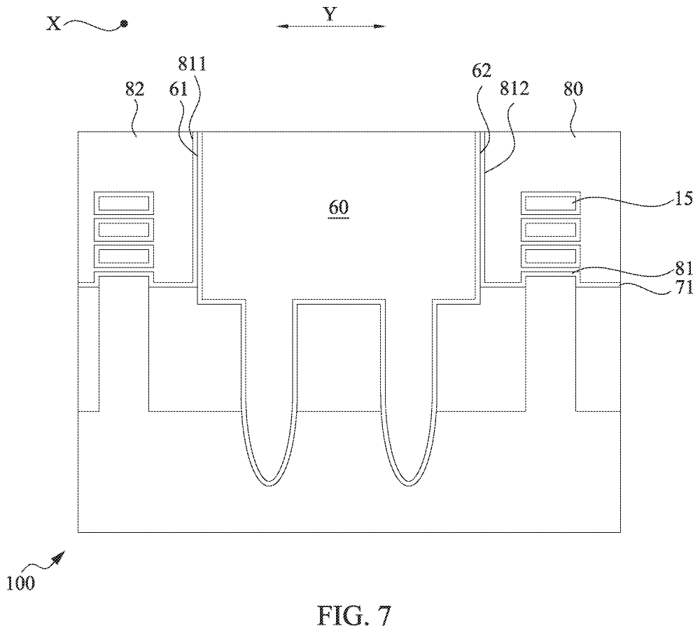

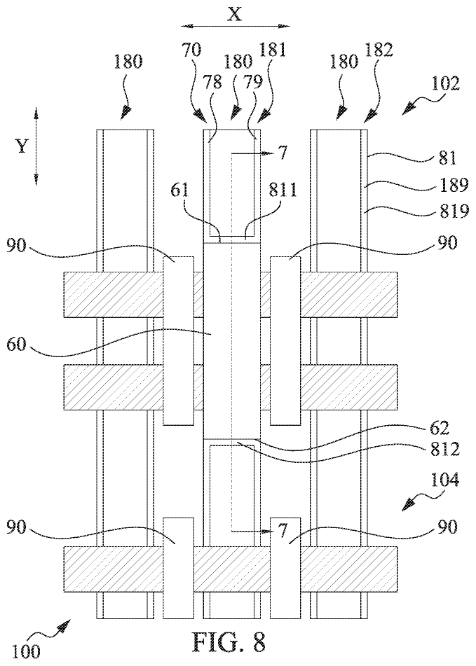

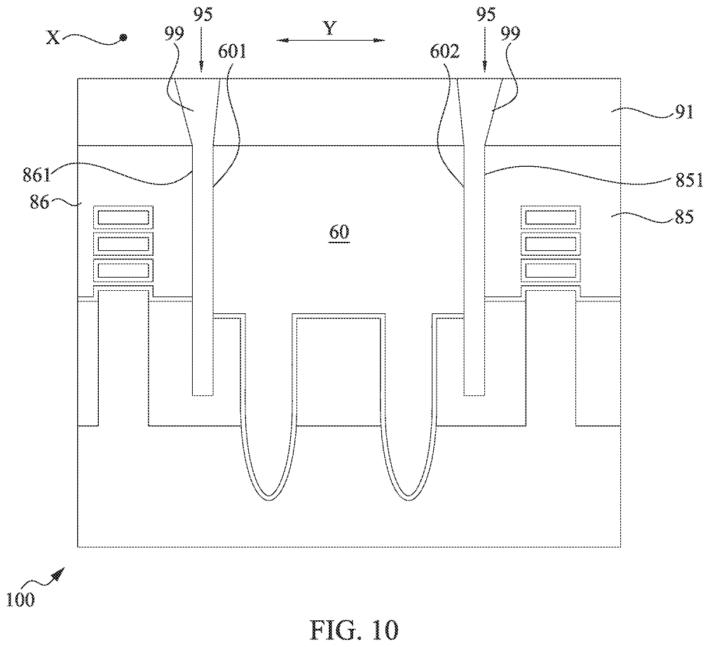

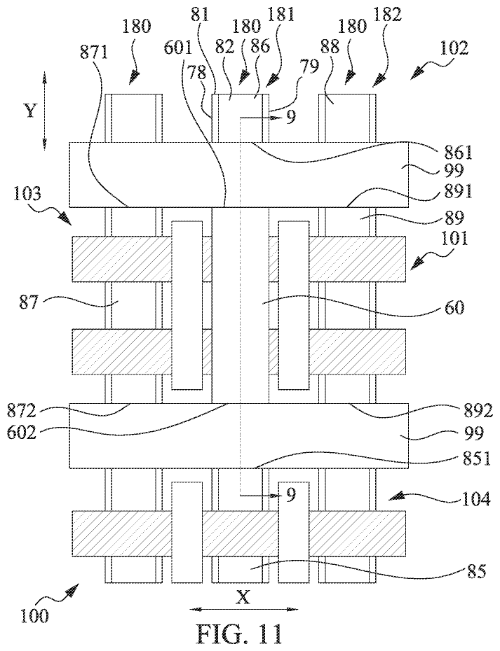

Method 200 is described below with reference to FIGS. 3-12 which illustrate the semiconductor device 100 at various stages of fabrication according to method 200. FIGS. 3-7 and 9-10 provide cross-sectional views of an embodiment of the semiconductor device 100 along a plane substantially parallel to a plane defined by an Y-axis through a gate line 30 in FIG. 1. FIG. 8 is an overhead view of the fabrication stage of FIG. 7. FIG. 11 is an overhead schematic of elements of the fabrication stage of FIG. 10.

The semiconductor device 100 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the semiconductor device 100 includes a plurality of semiconductor devices (e.g., transistors), including PFETs, NFETs, etc., which may be interconnected. Moreover, it is noted that the process steps of method 200, including any descriptions given with reference to the figures are merely exemplary and are not intended to be limiting beyond what is specifically recited in the claims that follow.

Method 200 begins at block S202 where a partially fabricated multi-gate device 100 is provided. Referring to the example of FIG. 3, in an embodiment of block S202, the method 200 forms structures 12, such as fins 12, over the substrate 10. The fins 12 extend in the X-direction and are distanced apart from one another in the Y-direction perpendicular to the X-direction. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

The fins 12 may include nanosheet channel layers, collectively identified by reference number 15 interleaved with sacrificial layers, collectively identified by reference number 16. In some embodiments, the nanosheet channel layers 15 may include silicon (Si) and sacrificial layers 16 may include silicon germanium (SiGe). However, in some embodiments, the nanosheet channel layers 15 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. By way of example, the nanosheet channel layers 15 may be epitaxially grown by a molecular beam epitaxy (MBE) process, a metalorganic chemical vapor deposition (MOCVD) process, and/or other suitable epitaxial growth processes.

In various embodiments, each of the fins 12 includes a substrate portion 13 formed from the substrate 10. It is noted that while the fins 12 are illustrated as including three (3) nanosheet channel layers 15, this is for illustrative purposes only and is not intended to be limiting beyond what is specifically recited in the claims. It can be appreciated that any number of nanosheet channel layers 15 can be formed, where for example, the number of nanosheet channel layers 15 depends on the desired number of channels regions for the GAA device (e.g., the device 100). In some embodiments, the number of nanosheet channel layers 15 is between three and ten.

Shallow trench isolation (STI) features 14 may also be formed interposing the fins 12. In some embodiments, the STI features 14 include SiO2, silicon nitride, silicon oxynitride, fluorine-doped silicate glass (FSG), a low-k dielectric, combinations thereof, and/or other suitable materials known in the art. In various examples, the dielectric layer used to form the STI features may be deposited by a CVD process, a subatmospheric CVD (SACVD) process, a flowable CVD process, an ALD process, a PVD process, and/or other suitable process.

As further shown in FIG. 3, the partially fabricated multi-gate device 100 further includes a sacrificial layer 17, such as a sacrificial or dummy gate structure 17 extending in the Y-direction. Sacrificial gate structures 17 are spaced from one another in the X-direction and are formed over portions of the fins 12 which are to be channel regions. The sacrificial gate structures 17 may extend over a number of adjacent fins 12 as shown. The sacrificial gate structures 17 lie directly over and define the channel regions of the GAA devices to be formed. Each of the sacrificial gate structures 17 may include a sacrificial gate dielectric and a sacrificial gate electrode over the sacrificial gate dielectric.

The sacrificial gate structures 17 are formed by first blanket depositing a sacrificial gate dielectric layer over the fins 12. A sacrificial gate electrode layer is then blanket deposited on the sacrificial gate dielectric layer and over the fins 12. The sacrificial gate dielectric layer includes silicon oxide, silicon nitride, or a combination thereof. The thickness of the sacrificial gate electrode layer is in a range from about 100 nm to about 200 nm in some embodiments. The sacrificial gate electrode layer includes silicon such as polycrystalline silicon or amorphous silicon. The thickness of the sacrificial gate dielectric layer is in a range from about 1 nm to about 5 nm in some embodiments. In some embodiments, the sacrificial gate structure 17 is subjected to a planarization operation. The sacrificial gate dielectric layer and the sacrificial gate electrode layer are deposited using CVD, including LPCVD and PECVD, PVD, ALD, or other suitable process. The sacrificial gate dielectric layer and the sacrificial gate electrode layer may be masked and patterned to form the sacrificial gate structures 17.

As shown, a mask layer 18 is formed over the sacrificial gate structures 17. The mask layer 18 may include a mask layer such as silicon oxide and a mask layer such as silicon nitride.

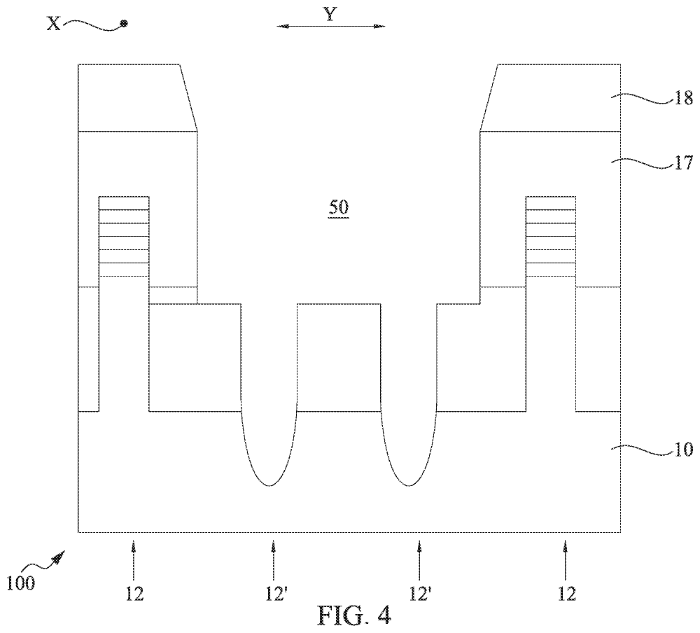

Cross-referencing FIGS. 2 and 4, method 200 may continue at block S204 with performing the CPODE etch process. Specifically, the mask layer is patterned before an etch is performed to remove a portion of the sacrificial gate structure 17 over lying selected fins 12′ for removal and to remove portions the selected fins 12′. As a result, a trench 50 is formed. In other words, method 200 includes removing a portion of at least one structure 12′ to form a trench 50. The trench 50 extends across the fins 12, i.e., in the Y-direction.

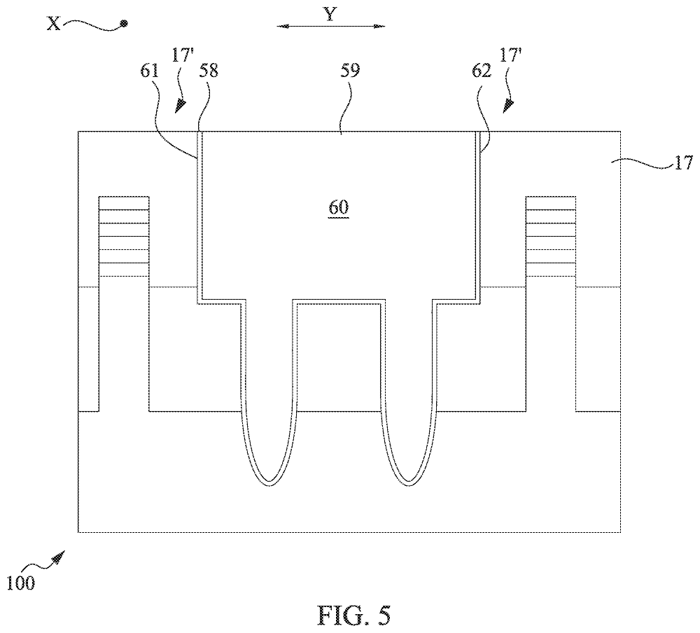

Cross-referencing FIGS. 2 and 5, method 200 may continue at block S206 with forming the CPODE insulation structure 60 in the trench. The CPODE insulation structure 60 may include an outer layer 58 conformally deposited along the walls of the trench and a fill material 59 deposited over the outer layer 58. For example, the layer 58 may be silicon nitride and the fill material 59 may be silicon oxide.

The CPODE insulation structure 60 extends in the Y-direction from a first end wall 61 to a second end wall 62. Thus, each end wall 61 and 62 extends in the X-direction. As shown in FIG. 5, adjacent portions 17′ of the sacrificial gate structure 17 are located adjacent to the end walls 61 and 62 of the CPODE insulation structure 60.

Thus, method 200 forms an insulation material 60 in the trench 50, and the insulation material 60 terminates at a first end wall 61, terminates at a second end wall 62, and extends in the Y-direction from the first end wall 61 to the second end wall 62.

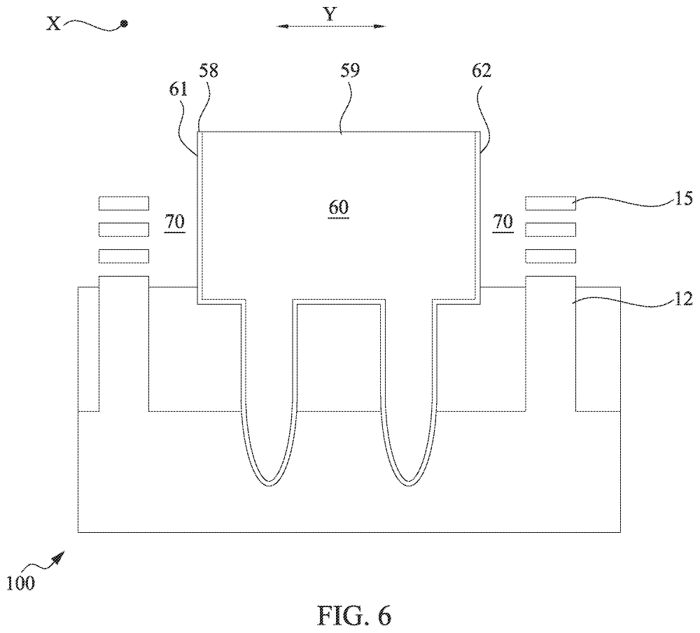

Cross-referencing FIGS. 2 and 6, method 200 may continue at block S208 with removing the sacrificial gate structures 17 to form gate cavities 70. As shown, the gate cavities 70 are partially defined by, i.e., bounded by, the end walls 61 and 62 of the CPODE insulation structure 60. Further, the sacrificial layers 16 are removed, leaving the nanosheet channel layers 15 spaced above the fins 12.

Cross-referencing FIGS. 2 and 7, method 200 may continue at block S210 with forming metal gates 80 in the gate cavities 70. Specifically, method 200 may include lining the gate cavities 70 with a liner 81. For example, a high-K gate dielectric layer 81 may be deposited along the end walls 61 and 62 that extend in the X-direction, along cavity sidewalls extending in the Y-direction (not shown in the cross-sectional view of FIG. 7), at the cavity bottom 71, and around the nanosheet channel layers 15. Thus, the liner 81 or high-K gate dielectric layer 81 includes an end portion 811, located on the end wall 61 of the CPODE insulation structure 60, and an end portion 812, located on the end wall 62 of the CPODE insulation structure 60. Each end portion 811 and 812 extends in the X-direction.

High-K gate dielectrics, as used and described herein, include dielectric materials having a high dielectric constant, for example, greater than that of thermal silicon oxide (about 3.9). An exemplary high-K gate dielectric layer 81 may include a high-K dielectric material such as hafnium oxide (HfO₂). Alternatively, the high-K gate dielectric layer 81 may include other high-K dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-K gate dielectric layer 81 may be formed by ALD, physical vapor deposition (PVD), CVD, oxidation, and/or other suitable methods.

Formation of the metal gates 80 further includes filling the gate cavities 70 with fill material 82. The fill material 82 may include multiple layers of a metal, metal alloy, or metal silicide. The fill material 82 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the fill material 82 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the fill material 82 may be formed by ALD, PVD, CVD, e-beam evaporation, or other suitable process. Further, the fill material 82 may be formed separately for N-type and P-type transistors which may use different metal layers. In addition, the fill material 82 may provide an N-type or P-type work function, may serve as a transistor gate electrode, and in at least some embodiments, the fill material 82 may include a polysilicon layer. In some examples, the fill material 82 may include selectively-grown tungsten (W) and/or a fluorine-free tungsten (FFW) layer.

As shown in FIG. 7, a chemical mechanical planarization (CMP) process may be performed to define the metal gates 80 in the gate cavities 70.

In summary, at block 201, method 200 forms a first element 80 adjacent to the first end wall 61, wherein a first terminal portion 811 of the first element 80 contacts the first end wall 61, and forms a second element 80 adjacent to the second end wall 62, wherein a second terminal portion 812 of the second element 80 contacts the second end wall 62.

Referring now to FIG. 8, an overhead schematic of the partially fabricated device 100 of FIG. 7 is shown, with the cross-sectional view of FIG. 7 taken along line 7-7 in FIG. 8.

FIG. 8 illustrates that the metal gates 80 are formed as metal gate lines 800 extending in the Y-direction, including metal gate line 181 and adjacent metal gate line 182. In each metal gate line 800, side portions 819 of the high-K dielectric layer 81 form the gate line sidewalls 189 that also extend in the Y-direction. As shown, the end portions 811 and 812 of the high-K dielectric layer 81 of metal gates 80 are located at the end walls 61 and 62, i.e., line ends, of the CPODE insulation structure 60. The end portions 811 and 812 extend in the X-direction. It has been found that the end portions 811 and 812 of the high-K dielectric layer 81 may cause parasitic capacitance when located near source/drain regions 90 and/or a shift of the threshold voltage. Therefore, embodiments herein remove the end portions 811 and 812 of the high-K dielectric layer 81.

As shown in FIG. 8, the metal gates 80 are formed in the gate cavities 70. In a gate cavity 70 formed in gate line 181, the cavity 70 is defined by the end wall 61 of the insulation structure 60, a first sidewall 78 extending away from the end wall 61, and a second sidewall 79 extending away from the end wall 61.

In summary, after etching the portion or portions of selected fins 12, the trench 50 is located between a first remaining structure or fin 12 in a device area 102 and a second remaining structure or fin 12 in a device area 104, and the method 200 includes forming a first metal gate 80 over the first remaining structure 12 in device area 102 and forming a second metal gate 80 over the second remaining structure 12 in device area 104. As shown, the first metal gate 80 in device area 102 and the second metal gate 80 in device area 104 are aligned in a gate line 181 extending in the Y-direction.

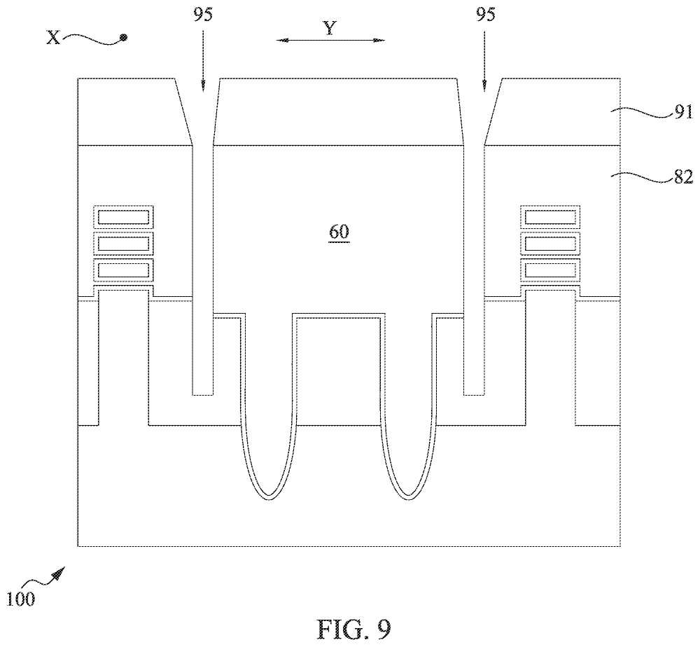

Cross-referencing FIGS. 2 and 9, method 200 continues at block S212 with removing the end portions 811 and 812 of the high-K dielectric layer 81. Specifically, a mask 91 is formed and patterned over the partially fabricated device 100. Then an etching process is performed to remove the end portions 811 and 812 of the high-K dielectric layer 81. The etching process may remove the end walls 61 and 62 of the CPODE insulation structure 60. Further, the etching process may remove portions of the metal fill 82 adjacent to the end portions 811 and 812 of the high-K dielectric layer 81. Also, the etching process may remove portions of the STI feature 14 previously lying under the end portions 811 and 812 of the high-K dielectric layer 81. As a result of removing the end portions 811 and 812 of the high-K dielectric layer 81, openings 95 are formed. The openings 95 may extend into the STI features 14.

In summary, at block S212, method 200 includes removing the first terminal portion 811 to form a first opening 95 and the second terminal portion 812 to form a second opening 95.

Cross-referencing FIGS. 8 and 9, it is noted that the etching process performed to remove the end portions 811 and 812 of the high-K dielectric layer 81 also includes removing portions of the adjacent gate lines 800. Specifically, the etching process that removes the end portions 811 and 812 of the high-K dielectric layer 81 is part of the cut-metal process for defining the metal gates 80 from the gate lines 800.

Cross-referencing FIGS. 2 and 10, method 200 continues at block S214 with forming end isolation structures 99 in the openings 95. End isolation structures 99 may be referred to as cut-metal dielectric structures 99. In exemplary embodiments, the end isolation structures 99 may include a layer or multiple layers formed from silicon oxide and/or silicon nitride.

Thereafter, method 200 may continue at block S216 with further processing, such as performing middle end of line (MEOL) processing and back end of line (BEOL) processing.

Referring now to FIG. 11, an overhead schematic of the device 100 of FIG. 10 is shown, with the cross-sectional view of FIG. 10 taken along line 9-9 in FIG. 11. As shown in FIGS. 10-11, the end portions 811 and 812 of the high-K dielectric layer 81 are removed and replaced by end isolation structures 99. The end isolation structures 99 extend across multiple gate lines 800, including gate lines 181 and 182, and isolate adjacent gate structures 80 within a gate line 800, such as gate structures 88 and 89, from one another. Gate structures 88 and 89 may be included in adjacent device areas 101 and 102. Accordingly, device areas 101 and 102 are separated from one another in the Y-direction. Likewise, the CPODE insulation structure 60 isolates adjacent device areas 101 and 103, that are separated from one another in the X-direction.

FIG. 11 illustrates that the second gate line 182 extending in the Y-direction is distanced from the first gate line 181 in the X-direction; that a first opening 95 in which an end isolation structure 99 is formed extends through the first gate line 181 and second gate line 182 to separate device area 101 from device area 102; and that a second opening 95 in which an end isolation structure 99 is formed extends through the first gate line 181 and second gate line 182 to separate device area 101 from device area 104.

As shown in FIG. 11, after removing the end portion 811 of the high-K dielectric layer 81, the high-K dielectric layer 81 remains located on the first sidewall 78 and the second sidewall 79 of the gate cavity 70.

Further, the high-K gate dielectric 81 is not located between the metal layer 82 and the dielectric structure 99. In other words, the metal layer 82 directly contacts the dielectric structure 99.

As shown in FIGS. 10 and 11, method 200 fabricates a semiconductor device 100 including a semiconductor substrate 10; a first device area 101 over the semiconductor substrate 10 and including a first metal gate 89 extending in a Y-direction to a first end 891; a second device area 103 over the semiconductor substrate 10, including a second metal gate 87 extending in a Y-direction to a first end 871, and distanced from the first device area 101 in the X-direction; an insulation structure 60 abutting the first device area 101 and the second device area 103 and located between the first device area 101 and the second device area 103, wherein the insulation structure 60 extends in the Y-direction to a first end 601; and a dielectric structure 99 extending in the X-direction, wherein the dielectric structure 99 abuts the first end 891 of the first metal gate 89, abuts the first end 601 of the insulation structure 60, and abuts the first end 871 of the second metal gate 87.

As further shown, the first metal gate 89 extends in the Y-direction from a second end 892 to the first end 891; the second metal gate 87 extends in the Y-direction from a second end 872 to the first end 871; the insulation structure 60 extends in the Y-direction from a second end 602 to the first end 601; and the device 100 further includes a dielectric structure 99 extending in the X-direction, wherein the dielectric structure 99 abuts the second end 892 of the first metal gate 89, abuts the second end 602 of the insulation structure 60, and abuts the second end 872 of the second metal gate 87.

In some embodiments, the device 100 further includes a third device area 102 over the semiconductor substrate 10 that includes a third metal gate 86 extending in the Y-direction to a first end 861, wherein the third metal gate 86 is co-linear with the insulation structure 60, and wherein the dielectric structure 60 abuts the first end 861 of the third metal gate 86.

In some embodiments, the device 100 further includes a fourth device area 104 over the semiconductor substrate 10 that includes a fourth metal gate 85 extending in the Y-direction to a first end 851, wherein the fourth metal gate 85 is co-linear with the insulation structure 60, and wherein the dielectric structure 60 abuts the first end 851 of the fourth metal gate 85.

As a result of the processing and structure described herein, embodiments are provided with reduced or eliminated parasitic capacitance, and without a shift of the threshold voltage that would otherwise result from the presence of high-K gate dielectric on the end wall of the CPODE insulation.

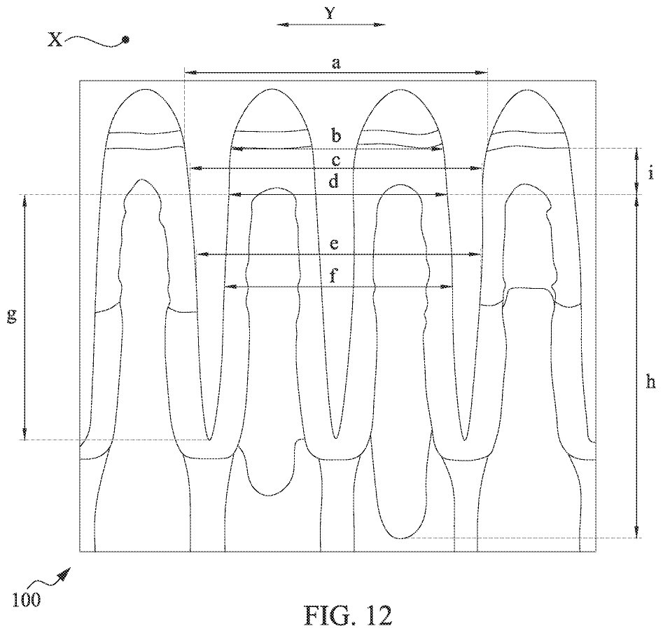

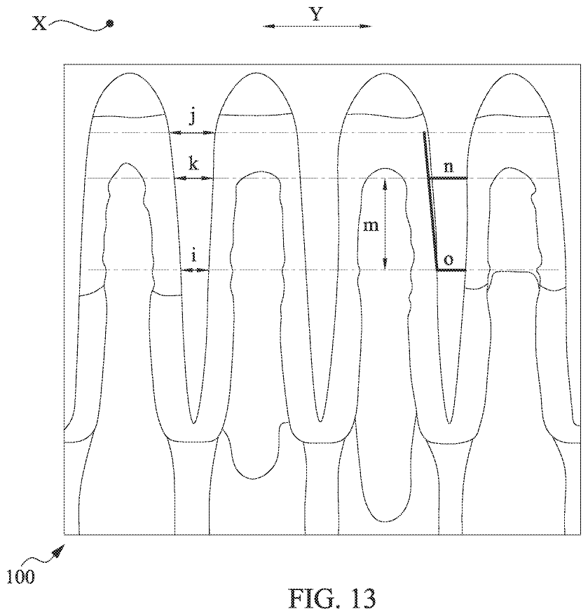

Referring now to FIGS. 12 and 13, transmission electron microscope (TEM) images of a portion of a semiconductor device 100 are provided.

In FIG. 12, after the cut-metal etching process, the device 100 has a maximum unit width at the hard mask of “a”, having a mean of 156.9 nm, a maximum of 157.1 nm, and a minimum of 156.5 nm; a maximum unit width at the hard mask of “b”, having a mean of 103.6 nm, a maximum of 104.6 nm, and a minimum of 102.7 nm; a maximum unit width at the uppermost nanosheet of “c”, having a mean of 152.2 nm, a maximum of 152.6 nm, and a minimum of 151.4 nm; a maximum unit width at the uppermost nanosheet of “d”, having a mean of 107.7 nm, a maximum of 109.0 nm, and a minimum of 106.9 nm; a maximum unit width at the upper surface of the fin, i.e., at the mesa, of “e”, having a mean of 146.5 nm, a maximum of 147.1 nm, and a minimum of 146.0 nm; a maximum unit width at the upper surface of the fin, i.e., at the mesa, of “f”, having a mean of 113.1 nm, a maximum of 113.9 nm, and a minimum of 111.8 nm; an cut-metal etch opening 95 depth of “g”, having a mean of 126.7 nm, a maximum of 133.2 nm, and a minimum of 121.1 nm; a CPODE etch trench 50 depth of “h”, having a mean of 173.0 nm, a maximum of 187.4 nm, and a minimum of 151.8 nm; and a gate height of “i”, having a mean of 23.5 nm, a maximum of 24.8 nm, and a minimum of 21.4 nm.

In FIG. 13, the device 100 has a cut-metal region critical dimension at the hard mask of “j”, having a mean of 26.6 nm, a maximum of 27.2 nm, and a minimum of 26.0 nm; a cut-metal region critical dimension at the uppermost nanosheet of “k”, having a mean of 22.2 nm, a maximum of 22.8 nm, and a minimum of 21.2 nm; a cut-metal region critical dimension at the upper surface of the fin, i.e., at the mesa, of “l”, having a mean of 16.7 nm, a maximum of 17.7 nm, and a minimum of 16.0 nm; a total nanosheet height of “m”, having a mean of 44.9 nm, a maximum of 46.5 nm, and a minimum of 43.6 nm; a cut-metal region angle at the uppermost nanosheet of “n”, having a mean of 46.6°, a maximum of 49.5°, and a minimum of 43.2°; and a cut-metal region angle at the upper surface of the fin, i.e., at the mesa, of “o”, having a mean of 69.6°, a maximum of 71.0°, and a minimum of 67.9°.

In some embodiments, the maximum overlay shift for the CPODE line end is 4 nm. Therefore, the cut-metal gate etch process will compensate for any overlay shift to ensure that the end portions 811 and 812 are removed.

Thus, one of the embodiments of the present disclosure describes a method including forming a fin structure over a semiconductor material; forming a sacrificial layer over the semiconductor material; removing at least a portion of the fin structure and an overlying portion of the sacrificial layer located over the portion of the fin structure to form a trench; forming an insulation structure in the trench, wherein an adjacent portion of the sacrificial layer is adjacent an end wall of the insulation structure; removing the adjacent portion of the sacrificial layer to form a cavity, wherein the cavity is partially defined by the end wall of the insulation structure; lining the cavity with a liner, wherein an end portion of the liner is located on the end wall of the insulation structure; filling the cavity with a fill material; removing the end portion of the liner to form an opening; and forming an end isolation structure in the opening.

In some embodiments of the method, the liner is a high-K gate dielectric layer and the fill material is a metal gate material.

In some embodiments of the method, the sacrificial layer is a sacrificial gate layer.

In some embodiments of the method, removing the end portion of the liner to form the opening includes removing a portion of the fill material and the end wall of the insulation structure.

In some embodiments of the method, lining the cavity with the liner and filling the cavity with the fill material includes forming a first gate line, and wherein a second gate line is formed parallel to the first gate line; a cut-metal process is performed to remove the end portion of the liner to form the opening; and the cut-metal process also removes a portion of the second gate line to form the opening.

In some embodiments of the method, the insulation structure is a continuous poly on diffusion edge (CPODE) structure; and the end isolation structure is a cut-metal isolation structure.

In some embodiments of the method, the cavity is defined by the end wall of the insulation structure, a first sidewall extending away from the end wall, and a second sidewall extending away from the end wall; lining the cavity with the liner includes forming the liner on the end wall, the first sidewall, and the second sidewall; and, after removing the end portion of the liner, the liner remains located on the first sidewall and the second sidewall.

In another of the embodiments of the present disclosure, a method for fabricating a semiconductor device is provided and includes forming structures over a semiconductor substrate, wherein the structures extend in an X-direction and are distanced apart from one another in a Y-direction perpendicular to the X-direction; removing a portion of at least one structure to form a trench; forming an insulation material in the trench, wherein the insulation material terminates at a first end wall, terminates at a second end wall, and extends in the Y-direction from the first end wall to the second end wall; forming a first element adjacent to the first end wall, wherein a first terminal portion of the first element contacts the first end wall; forming a second element adjacent to the second end wall, wherein a second terminal portion of the second element contacts the second end wall; and removing the first terminal portion to form a first opening and the second terminal portion to form a second opening.

In some embodiments, the method further includes forming a first insulation region in the first opening; and forming a second insulation region in the second opening.

In some embodiments of the method, the first terminal portion is a high-K dielectric; and the second terminal portion is a high-K dielectric.

In some embodiments, the method further includes forming a shallow trench isolation layer over the semiconductor substrate and between the structures; wherein: the first element is located over the shallow trench isolation layer; the second element is located over the shallow trench isolation layer; removing the first terminal portion to form the first opening includes etching into the shallow trench isolation layer; and removing the second terminal portion to form the second opening includes etching into the shallow trench isolation layer.

In some embodiments of the method, the portion of the at least one structure is located between a first remaining structure and a second remaining structure; forming the first element includes forming a first metal gate over the first remaining structure; and forming the second element includes forming a second metal gate over the second remaining structure, wherein the first metal gate and the second metal gate are aligned in a first gate line extending in the Y-direction.

In some embodiments, the method further includes forming a second gate line extending in the Y-direction and distanced from the first gate line in the X-direction; wherein the first opening extends through the second gate line, wherein the second opening extends through the second gate line, and wherein a second gate structure is defined between the first opening and the second opening.

In some embodiments of the method, the structures include fins; the method further includes forming a sacrificial gate over the fins; removing the portion of at least one structure to form the trench includes etching a selected portion of at least one fin and a portion of the sacrificial gate over the selected portion; the method further includes removing an adjacent portion of the sacrificial structure to form a gate cavity after forming the insulation material in the trench; the first element is a first metal gate; and forming the first element adjacent to the first end wall includes forming the first metal gate in the gate cavity.

In another of the embodiments of the present disclosure, a semiconductor device includes a semiconductor substrate; a first device area over the semiconductor substrate and including a first metal gate extending in a Y-direction to a first end; a second device area over the semiconductor substrate and distanced from the first device area in an X-direction perpendicular to the Y-direction; an insulation structure abutting the first device area and the second device area and located between the first device area and the second device area, wherein the insulation structure extends in the Y-direction to a first end; and a dielectric structure extending in the X-direction, wherein the dielectric structure abuts the first end of the first metal gate and the first end of the insulation structure.

In some embodiments of the semiconductor device, the second device area includes a second metal gate extending in a Y-direction to a first end; and the dielectric structure abuts the first end of the first metal gate, the first end of the insulation structure, and the first end of the second metal gate.

In some embodiments of the semiconductor device, the first metal gate extends in the Y-direction from a second end to the first end; the second metal gate extends in the Y-direction from a second end to the first end; the insulation structure extends in the Y-direction from a second end to the first end; the dielectric structure is a first dielectric structure; the semiconductor device further includes a second dielectric structure extending in the X-direction; and the second dielectric structure abuts the second end of the first metal gate, the second end of the insulation structure, and the second end of the second metal gate.

In some embodiments, the semiconductor device further includes a third device area over the semiconductor substrate and including a third metal gate extending in a Y-direction to a first end, wherein the third metal gate is co-linear with the insulation structure, and wherein the dielectric structure abuts the first end of the third metal gate.

In some embodiments of the semiconductor device, the third metal gate includes a high-K gate dielectric and a metal layer; and the high-K gate dielectric is not located between the metal layer and the dielectric structure.

In some embodiments of the semiconductor device, the third metal gate includes a high-K gate dielectric and a metal layer; and the metal layer directly contacts the dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
forming a fin structure over a semiconductor material;
forming a sacrificial layer over the semiconductor material;
removing at least a portion of the fin structure and an overlying portion of the sacrificial layer located over the portion of the fin structure to form a trench;
forming an insulation structure in the trench, wherein an adjacent portion of the sacrificial layer is adjacent an end wall of the insulation structure;
removing the adjacent portion of the sacrificial layer to form a cavity, wherein the cavity is partially defined by the end wall of the insulation structure;
lining the cavity with a liner, wherein an end portion of the liner is located on the end wall of the insulation structure;
filling the cavity with a fill material;
removing the end portion of the liner to form an opening; and
forming an end isolation structure in the opening.

2. The method of claim 1, wherein the liner is a high-K gate dielectric layer and wherein the fill material is a metal gate material.

3. The method of claim 1, wherein the sacrificial layer is a sacrificial gate layer.

4. The method of claim 1, wherein removing the end portion of the liner to form the opening comprises removing a portion of the fill material and the end wall of the insulation structure.

5. The method of claim 1, wherein:
lining the cavity with the liner and filling the cavity with the fill material comprises forming a first gate line, and wherein a second gate line is formed parallel to the first gate line;
a cut-metal process is performed to remove the end portion of the liner to form the opening; and
the cut-metal process also removes a portion of the second gate line to form the opening.

6. The method of claim 1, wherein:
the insulation structure is a continuous poly on diffusion edge (CPODE) structure; and
the end isolation structure is a cut-metal isolation structure.

7. The method of claim 1, wherein:
the cavity is defined by the end wall of the insulation structure, a first sidewall extending away from the end wall, and a second sidewall extending away from the end wall;
lining the cavity with the liner comprises forming the liner on the end wall, the first sidewall, and the second sidewall; and
after removing the end portion of the liner, the liner remains located on the first sidewall and the second sidewall.

8. A method for fabricating a semiconductor device, the method comprising:
forming structures over a semiconductor substrate, wherein the structures extend in an X-direction and are distanced apart from one another in a Y-direction perpendicular to the X-direction;
removing a portion of at least one structure to form a trench;
forming an insulation material in the trench, wherein the insulation material terminates at a first end wall, terminates at a second end wall, and extends in the Y-direction from the first end wall to the second end wall;
forming a first element adjacent to the first end wall, wherein a first terminal portion of the first element contacts the first end wall;
forming a second element adjacent to the second end wall, wherein a second terminal portion of the second element contacts the second end wall; and
removing the first terminal portion to form a first opening and the second terminal portion to form a second opening.

9. The method of claim 8, further comprising:
forming a first insulation region in the first opening; and
forming a second insulation region in the second opening.

10. The method of claim 8, wherein:
the first terminal portion is a high-K dielectric; and
the second terminal portion is a high-K dielectric.

11. The method of claim 8, further comprising forming a shallow trench isolation layer over the semiconductor substrate and between the structures; wherein:
the first element is located over the shallow trench isolation layer;
the second element is located over the shallow trench isolation layer;
removing the first terminal portion to form the first opening comprises etching into the shallow trench isolation layer; and
removing the second terminal portion to form the second opening comprises etching into the shallow trench isolation layer.

12. The method of claim 8, wherein:
the portion of the at least one structure is located between a first remaining structure and a second remaining structure;
forming the first element comprises forming a first metal gate over the first remaining structure; and
forming the second element comprises forming a second metal gate over the second remaining structure, wherein the first metal gate and the second metal gate are aligned in a first gate line extending in the Y-direction.

13. The method of claim 12, further comprising:
forming a second gate line extending in the Y-direction and distanced from the first gate line in the X-direction; wherein the first opening extends through the second gate line, wherein the second opening extends through the second gate line, and wherein a second gate structure is defined between the first opening and the second opening.

14. The method of claim 8, wherein:
the structures comprise fins;
the method further comprises forming a sacrificial gate over the fins;
removing the portion of at least one structure to form the trench comprises etching a selected portion of at least one fin and a portion of the sacrificial gate over the selected portion;
the method further comprises removing an adjacent portion of the sacrificial structure to form a gate cavity after forming the insulation material in the trench;
the first element is a first metal gate; and
forming the first element adjacent to the first end wall comprises forming the first metal gate in the gate cavity.

15. A semiconductor device comprising:
a semiconductor substrate;
a first device area over the semiconductor substrate and comprising a first metal gate extending in a Y-direction to a first end;
a second device area over the semiconductor substrate and distanced from the first device area in an X-direction perpendicular to the Y-direction;
an insulation structure abutting the first device area and the second device area and located between the first device area and the second device area, wherein the insulation structure extends in the Y-direction to a first end; and
a dielectric structure extending in the X-direction, wherein the dielectric structure abuts the first end of the first metal gate and the first end of the insulation structure.

16. The semiconductor device of claim 15, wherein:
the second device area comprises a second metal gate extending in a Y-direction to a first end;
the dielectric structure abuts the first end of the first metal gate, the first end of the insulation structure, and the first end of the second metal gate.

17. The semiconductor device of claim 16, wherein:
the first metal gate extends in the Y-direction from a second end to the first end;
the second metal gate extends in the Y-direction from a second end to the first end;
the insulation structure extends in the Y-direction from a second end to the first end;
the dielectric structure is a first dielectric structure;
the semiconductor device further comprises a second dielectric structure extending in the X-direction; and
the second dielectric structure abuts the second end of the first metal gate, the second end of the insulation structure, and the second end of the second metal gate.

18. The semiconductor device of claim 15, further comprising:
a third device area over the semiconductor substrate and comprising a third metal gate extending in a Y-direction to a first end, wherein the third metal gate is co-linear with the insulation structure, and wherein the dielectric structure abuts the first end of the third metal gate.

19. The semiconductor device of claim 18, wherein:
the third metal gate comprises a high-K gate dielectric and a metal layer; and
the high-K gate dielectric is not located between the metal layer and the dielectric structure.

20. The semiconductor device of claim 18, wherein:
the third metal gate comprises a high-K gate dielectric and a metal layer; and
the metal layer directly contacts the dielectric structure.
